(19) United States
(12) Patent Application Publication
(10) Pub. No.: US 2023/0389362 A1
(43) Pub. Date: Nov. 30, 2023

(54) DISPLAY APPARATUS AND METHOD OF MANUFACTURING THE SAME

(71) Applicant: Samsung Display Co., Ltd., Yongin-si (KR)

(72) Inventor: Chungi You, Yongin-si (KR)

(73) Assignee: Samsung Display Co., Ltd., Yongin-si (KR)

(21) Appl. No.: 18/107,099

(22) Filed: Feb. 8, 2023

(30) Foreign Application Priority Data
May 27, 2022 (KR) 10-2022-0065595

(51) Int. Cl. H10K 59/122; H10K 59/12; H10K 71/00

(52) U.S. Cl. CPC H10K 59/122; H10K 59/1201; H10K 71/00

(57) ABSTRACT

A display apparatus includes a pixel electrode disposed on a substrate, a pixel-defining layer disposed on the pixel electrode and having an opening exposing at least a portion of the pixel electrode, a cured layer disposed on the pixel-defining layer, and an opposite electrode disposed on the cured layer, the cured layer includes a material forming a crosslinked structure through carbon-carbon bonds.

### CROSS-REFERENCE TO RELATED APPLICATION(S)

This application claims priority to and benefits of Korean Patent Application No. 10-2022-0065595 under 35 U.S.C. § 119, filed on May 27, 2022, in the Korean Intellectual Property Office, the entire contents of which are incorporated herein by reference.

### BACKGROUND

### 1. Technical Field

One or more embodiments relate to a display apparatus and a method of manufacturing the same, and, to a display apparatus including a light-emitting element with improved light emission performance, and a method of manufacturing the display apparatus.

### 2. Description of the Related Art

Display apparatuses are devices for visually displaying data. Display apparatuses are used as displays of compact products such as mobile phones or of large-sized products such as televisions.

Display apparatuses include pixels which receive an electrical signal to emit light to thereby display an image to the outside. Each pixel may include a light-emitting element. For example, an organic light-emitting display apparatus may include an organic light-emitting diode (OLED) as a light-emitting element. In general, an organic light-emitting display apparatus may include a thin-film transistor and an organic light-emitting diode formed on a substrate, and operates with the organic light-emitting diode emitting light by itself.

As the usage of display apparatuses has recently been diversified, various attempts are being made to make designs for improving the quality of display apparatuses. For example, research into improving the light emission performance of a light-emitting element included in display apparatuses is actively being conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display apparatus including a light-emitting element having improved light emission performance and a method of manufacturing the same. However, the above objective is an example, and the scope of the disclosure is not limited by the above objective.

Additional aspects will be set forth in part in the description which follows and, in part, will be apparent from the description, or may be learned by practice of the embodiments of the disclosure.

According to one or more embodiments, a display apparatus may include a pixel electrode disposed on a substrate; a pixel-defining layer disposed on the pixel electrode and having an opening exposing at least a portion of the pixel electrode; a cured layer disposed on the pixel-defining layer; and an opposite electrode disposed on the cured layer, wherein the cured layer may include a material forming a crosslinked structure through carbon-carbon bonds.

In an embodiment, a thickness of the cured layer may be in a range of about 100 Å to about 500 Å.

In an embodiment, the cured layer may be hydrophobic.

In an embodiment, the cured layer may have a different chemical structure from a chemical structure of a material included in the pixel-defining layer.

In an embodiment, the pixel-defining layer may include photosensitive polyimide (PSPI).

In an embodiment, the material forming the crosslinked structure in the cured layer may include a PSPI monomer.

In an embodiment, the display apparatus may further include an intermediate layer disposed on the pixel electrode.

In an embodiment, the opposite electrode may cover the intermediate layer and the cured layer.

According to one or more embodiment, a method of manufacturing a display apparatus, may include forming a pixel electrode on a substrate; forming a pixel-defining layer disposed on the pixel electrode and having an opening exposing at least a portion of the pixel electrode; and forming a cured layer on the pixel-defining layer by plasma treatment, wherein the cured layer is formed by cross-linking of a material included in the pixel-defining layer, and the cured layer has weaker moisture adsorption capacity than the pixel-defining layer.

In an embodiment, a thickness of the cured layer may be in a range of about 100 Å to about 500 Å.

In an embodiment, the pixel-defining layer may include photosensitive polyimide (PSPI).

In an embodiment, the forming of the cured layer on the pixel-defining layer by plasma treatment may include chain scission in which carbon-nitrogen bonds are broken in the pixel-defining layer.

In an embodiment, the method may further include forming a crosslinked structure through carbon-carbon bonds in the pixel-defining layer after the chain scission.

In an embodiment, the forming of the cured layer on the pixel-defining layer by plasma treatment may be performed using light of a wavelength in a range of about 300 nm to about 500 nm.

In an embodiment, the forming of the cured layer on the pixel-defining layer by plasma treatment may be performed by using a gas containing helium (He).

In an embodiment, the forming of the cured layer on the pixel-defining layer by plasma treatment may be performed in a range of about 30 seconds to about 50 seconds.

In an embodiment, a flow rate of the gas containing (He) may be in a range of about 1000 sccm to about 2000 sccm.

In an embodiment, the forming of the cured layer on the pixel-defining layer by plasma treatment may be performed with a process power including a source power in a range of about 2500 W to about 3500 W and a bias power in a range of about 500 W to about 1500 W, at a process pressure in a range of about 8 mT to about 50 mT.

In an embodiment, the method may further include forming an intermediate layer on the pixel electrode after the forming of the cured layer.

In an embodiment, the method may further include forming an opposite electrode covering the intermediate layer and the cured layer after the forming of the intermediate layer.

In addition to the aforesaid details, other aspects, features, and advantages will be clarified from the following drawings, claims, and detailed description.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic plan view schematically illustrating a display apparatus according to an embodiment;

FIG. 2 is a schematic plan view schematically illustrating a display panel according to an embodiment;

FIG. 3 is a schematic diagram of an equivalent circuit of any one pixel that may be included in a display apparatus according to an embodiment;

FIGS. 4 and 5 are flowcharts of a method of manufacturing a display apparatus, according to an embodiment;

FIGS. 6 to 11 are schematic cross-sectional views sequentially illustrating a method manufacturing a display apparatus, according to an embodiment;

FIG. 12 is a schematic diagram illustrating chemical formulae of materials that may be included in an embodiment; and

FIG. 13 shows a graph showing a thickness whereby light penetrates through a pixel-defining layer according to wavelengths during plasma treatment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects of the description.

As used herein, the singular forms, “a,” “an,” and “the” are intended to include the plural forms as well, unless the context clearly indicates otherwise.

As used herein, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Throughout the disclosure, the expression “at least one of a, b and c” indicates only a, only b, only c, both a and b, both a and c, both b and c, all of a, b, and c, or variations thereof.

As the disclosure allows for various changes and numerous embodiments, embodiments will be illustrated in the drawings and described in detail in the written description. The effects and features of the disclosure, and ways to achieve them will become apparent by referring to embodiments that will be described later in detail with reference to the drawings. However, the disclosure is not limited to the following embodiments but may be embodied in various forms.

Hereinafter, embodiments of the disclosure will be described in detail with reference to the accompanying drawings, and in the description with reference to the drawings, like reference numerals refer to like elements and redundant descriptions thereof may be omitted.

It will be understood that although the terms “first,” “second,” etc. may be used herein to describe various elements, these elements should not be limited by these terms. These terms are only used to distinguish one element from another. It will be understood that, although the terms first, second, etc., may be used herein to describe various elements, these elements should not be limited by these terms. For example, a first element may be referred to as a second element, and similarly, a second element may be referred to as a first element without departing from the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

In embodiments, it will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Also, in the drawings, for convenience of description, sizes of elements may be exaggerated or contracted. For example, since sizes and thicknesses of elements in the drawings are arbitrarily illustrated for convenience of explanation, the following embodiments are not limited thereto.

When an embodiment is implementable in another manner, a given process order may be different from a described one. For example, two processes that are consecutively described may be substantially simultaneously performed or may be performed in an opposite order to the described order.

In the following embodiments, when layers, regions, or elements are described as being connected, other layers, this indicates a case where layers, regions, and elements are directly connected or/and a case where layers, regions, and elements are indirectly connected with other layers, regions, and elements therebetween.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

An x-axis, a y-axis, and a z-axis are not limited to three axes on a rectangular coordinate system but may be construed as including these axes. For example, an-x axis, a y-axis, and a z-axis may be at right angles or may also indicate different directions from one another, which are not at right angles.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the attached drawings.

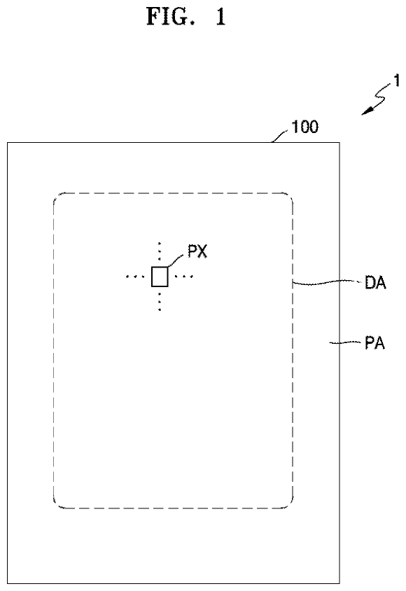

FIG. 1 is a schematic plan view schematically illustrating a display apparatus according to an embodiment.

Referring to FIG. 1, a display apparatus 1 may include a display area DA in which an image is realized and a peripheral area PA arranged or disposed around or adjacent to the display area DA. The display apparatus 1 may provide an image to the outside by using light emitted from the display area DA.

A substrate 100 may include various materials such as glass, metal or plastic. According to an embodiment, the substrate 100 may include a flexible material. The flexible material refers to a substrate that is readily bendable, curvable or foldable or rollable. The substrate 100 including a flexible material as above may include ultra-thin glass, metal or plastic.

In the display area DA of the substrate 100, pixels PX having various display elements such as an organic light-emitting diode may be arranged. The pixels PX may be formed in plural, and the pixels PX may be arranged in various forms such as a stripe arrangement, a PENTILE™ arrangement, and a mosaic arrangement to realize an image.

In case that the display area DA is viewed in a planar shape, the display area DA may have a rectangular shape as illustrated in FIG. 1. In an embodiment, the display area DA may be provided in a polygonal shape such as a triangle, a pentagon, or a hexagon, or a circular shape, an elliptical shape, or an irregular shape. It is to be understood that the shapes disclosed herein may also include shapes substantial to the shapes disclosed herein.

The peripheral area PA of the substrate 100 is an area arranged around the display area DA, and may be an area in which an image is not displayed. In the peripheral area PA, various wires that transmit electrical signals to be applied to the display area DA and pads to which a printed circuit board or a driver integrated circuit (IC) chip is attached may be located or disposed.

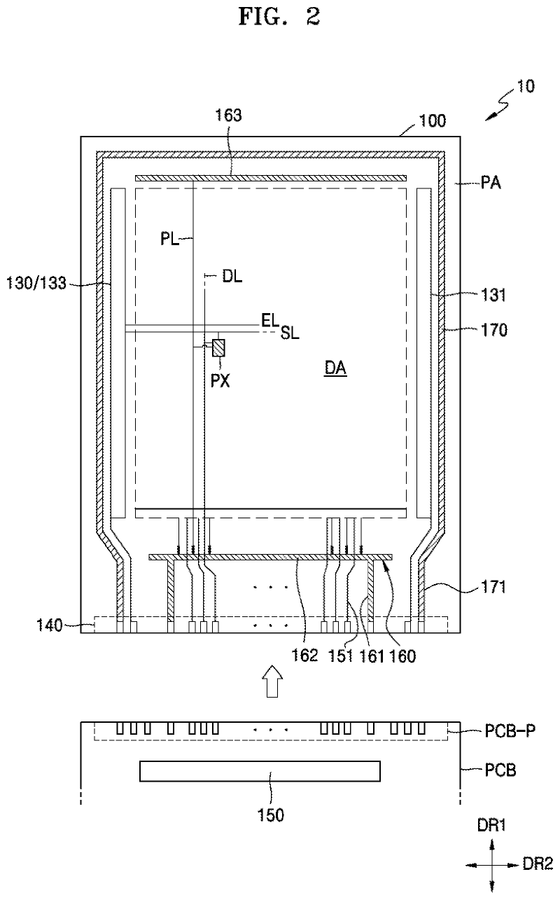

FIG. 2 is a schematic plan view schematically illustrating a display panel according to an embodiment.

Referring to FIG. 2, the display panel 10 may include a display area DA and a peripheral area PA, and may include pixels PX arranged in the display area DA. Each of the pixels PX may include a display element such as an organic light-emitting diode. Each pixel PX may emit, for example, red, green, blue or white light through the organic light-emitting diode. Hereinafter, in the specification, each pixel PX means a sub-pixel emitting light of different colors, and each pixel PX may be one of, for example, a red (R) sub-pixel, a green (G) sub-pixel, and a blue (B) sub-pixel. The display area DA may be covered with an encapsulation member (not shown) to be protected from external air or moisture.

Each pixel PX may be electrically connected to external circuits arranged in the peripheral area PA. A first scan driving circuit 130, a second scan driving circuit 131, an emission control driving circuit 133, a terminal 140, a data driving circuit 150, a first power supply wire 160, and a second power supply wire 170 may be arranged in the peripheral area PA.

The first scan driving circuit 130 and the second scan driving circuit 131 may provide a scan signal to each pixel PX through a scan line SL. The second scan driving circuit 131 may be arranged in parallel with the first scan driving circuit 130 with the display area DA therebetween. Some or a number of the pixels PX arranged in the display area DA may be electrically connected to the first scan driving circuit 130, and others may be connected to the second scan driving circuit 131. In an embodiment, the second scan driving circuit 131 may be omitted.

The emission control driving circuit 133 may provide an emission control signal to each pixel PX through an emission control line EL.

The terminal 140 may be arranged at one side or a side of the substrate 100. The terminal 140 may be exposed without being covered by an insulating layer and be electrically connected to a printed circuit board PCB. A terminal PCB-P of the printed circuit board PCB may be electrically connected to the terminal 140 of the display panel 10. The printed circuit board PCB may transmit a signal or power from a controller (not shown) to the display panel 10.

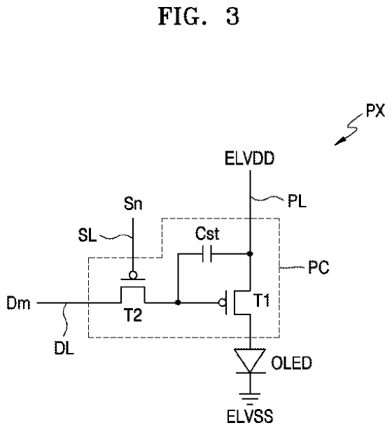

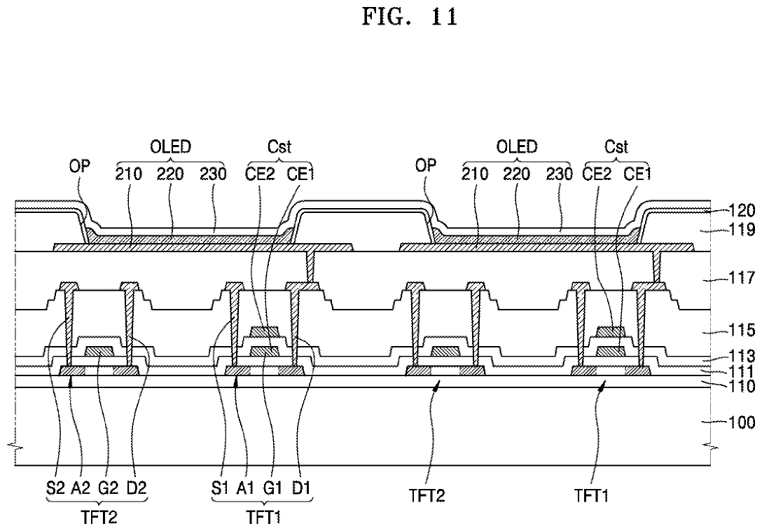

A control signal generated in the controller may be transmitted to each of the first scan driving circuit 130 and the second scan driving circuit 131 through the printed circuit board PCB. The controller may provide a first power voltage ELVDD and a second power voltage ELVSS (see FIG. 3 to be described later) to the first power supply wire 160 and the second power supply wire 170 through a first connection wire 161 and a second connection wire 171, respectively. The first power voltage ELVDD may be provided to each pixel PX through a driving voltage line PL connected to the first power supply wire 160, and the second power voltage ELVSS may be provided to an opposite electrode 230 (see FIG. 11 to be described later) of each pixel PX connected to the second power supply wire 170.

The data driving circuit 150 is electrically connected to a data line DL. A data signal of the data driving circuit 150 may be provided to each pixel PX through a connection wire 151 connected to the terminal 140 and the data line DL connected to the connection wire 151. While FIG. 2 illustrates that the data driving circuit 150 is disposed on the printed circuit board PCB, in an embodiment, the data driving circuit 150 may be disposed on the substrate 100. For example, the data driving circuit 150 may be arranged between the terminal 140 and the first power supply wire 160.

The first power supply wire 160 may include a first sub-wire 162 and a second sub-wire 163 extending in parallel to each other along a second direction DR2 with the display area DA therebetween. The second power supply wire 170 may partially surround the display area DA in a loop shape with one side or a side open.

FIG. 3 is a schematic diagram of an equivalent circuit of any one pixel that may be included in a display apparatus according to an embodiment.

Referring to FIG. 3, each pixel PX may include a pixel circuit PC connected to the scan line SL and the data line DL and an organic light-emitting diode OLED connected to the pixel circuit PC.

The pixel circuit PC may include a driving thin-film transistor T1, a switching thin-film transistor T2, and a storage capacitor Cst. The switching thin-film transistor T2 is connected to the scan line SL and the data line DL, and may transmit, to the driving thin-film transistor T1, a data signal Dm that is input through the data line DL according to a scan signal Sn input through the scan line SL.

The storage capacitor Cst is connected to the switching thin-film transistor T2 and the driving voltage line PL, and stores a voltage corresponding to a difference between a voltage received from the switching thin-film transistor T2 and the first power voltage ELVDD supplied to the driving voltage line PL.

The driving thin-film transistor T1 is connected to the driving voltage line PL and the storage capacitor Cst, and may control, in response to a voltage value stored in the storage capacitor Cst, a driving current flowing from the driving voltage line PL and through the organic light-emitting diode OLED. The organic light-emitting diode OLED may emit light having a given luminance according to the driving current.

While the pixel circuit PC including two thin-film transistors and one storage capacitor is described with reference to FIG. 3, the disclosure is not limited thereto. For example, the pixel circuit PC may include three or more thin-film transistors and/or two or more storage capacitors.

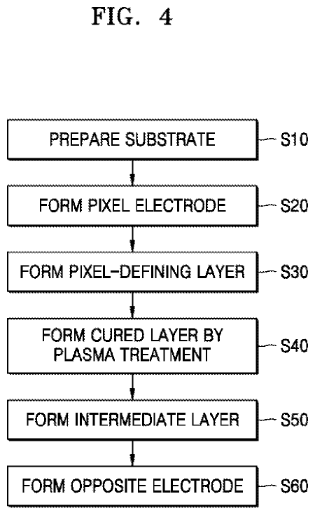

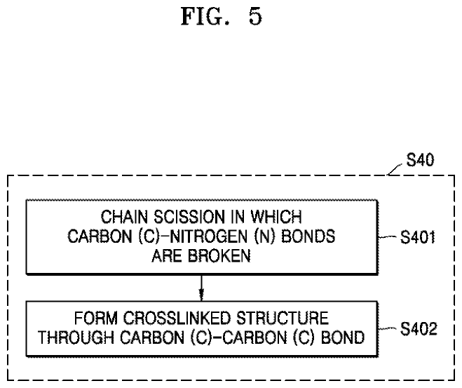

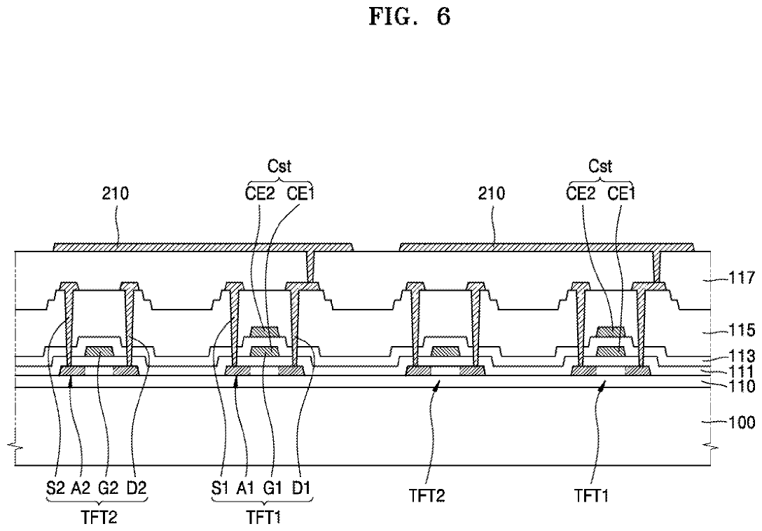

FIGS. 4 and 5 are flowcharts of a method of manufacturing a display apparatus, according to an embodiment, and FIGS. 6 to 11 are schematic cross-sectional views sequentially illustrating a method of manufacturing a display apparatus, according to an embodiment.

Referring to FIG. 4, the method of manufacturing the display apparatus 1 (see FIG. 1), according to an embodiment, may include: preparing the substrate 100 (S10); forming a pixel electrode 210 on the substrate 100 (S20); forming a pixel-defining layer 119 (S30); forming a cured layer 120 by performing plasma treatment on the pixel-defining layer 119 (S40); forming an intermediate layer 220 (S50); and forming the opposite electrode 230 (S60).

Referring to FIG. 5, in an embodiment, the forming of the cured layer 120 by performing plasma treatment on the pixel-defining layer 119 (S40) may include: a chain scission in which carbon-nitrogen bonds are broken (S401); and forming a crosslinked structure through carbon-carbon bonds (S402).

Hereinafter, a method of manufacturing a display apparatus, according to an embodiment, will be sequentially described with reference to FIGS. 6 to 11.

Referring to FIG. 6, first, a substrate is prepared in operation S10.

The substrate 100 may include a glass material, a ceramic material, a metal material, or a flexible or bendable material. In case that the substrate 100 has flexible or bendable properties, the substrate 100 may include a polymer resin, for example, polyethersulfone, polyacrylate, polyetherimide, polyethylene naphthalate, polyethylene terephthalate, polyphenylene sulfide, polyarylate, polyimide, polycarbonate or cellulose acetate propionate.

The substrate 100 may have a single-layer or multi-layer structure of the above materials, and may further include an inorganic layer in a case of a multi-layer structure. In an embodiment, the substrate 100 may have an organic/inorganic/organic structure.

A buffer layer 110, semiconductor layers A1 and A2, first and second gate insulating layers 111 and 113, gate electrodes G1 and G2, and a lower electrode CE1 and an upper electrode CE2 of the storage capacitor Cst, an interlayer insulating layer 115, and a planarization layer 117 may be sequentially formed on the substrate 100.

The buffer layer 110 may include silicon oxide (SiO₂) or silicon nitride (SiNₓ), and may be formed by a deposition method such as chemical vapor deposition (CVD) or sputtering.

A barrier layer (not shown) may be further included between the substrate 100 and the buffer layer 110. The barrier layer may have a function of preventing or minimizing penetration of impurities from the substrate 100 or the like into the semiconductor layers A1 and A2. The barrier layer may include an inorganic material such as an oxide or a nitride, an organic material, or an organic-inorganic composite, and may have a single-layer or multi-layer structure of an inorganic material and an organic material.

The semiconductor layers A1 and A2 may be disposed on the buffer layer 110. The semiconductor layers A1 and A2 may be formed by patterning a preliminary semiconductor layer (not shown). The preliminary semiconductor layer may include an amorphous silicon or oxide semiconductor, and may be deposited by CVD. In case that the preliminary semiconductor layer may include an amorphous silicon layer, after forming the amorphous silicon layer, the amorphous silicon layer may be crystallized using various methods and formed into a polycrystalline silicon layer, wherein the methods include a rapid thermal annealing (RTA) method, a solid phase crystallzation (SPC) method, an excimer laser annealing (ELA) method, a metal induced crystallzation (MIC) method, a metal induced lateral crystallzation (MILC) method, a sequential lateral solidification (SLS) method, or the like within the spirit and the scope of the disclosure.

In an embodiment, the semiconductor layers A1 and A2 may include an oxide of at least one material selected from indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn).

The semiconductor layers A1 and A2 may include a channel region and a source region and a drain region arranged on both sides of the channel region. The semiconductor layers A1 and A2 may include a single layer or multiple layers.

The first gate insulating layer 111 and the second gate insulating layer 113 may be stacked each other on the substrate 100 to cover the semiconductor layers A1 and A2. The first and second gate insulating layers 111 and 113 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), and the like, and may be formed by a deposition method such as CVD or sputtering, but is not limited thereto.

The gate electrodes G1 and G2 may be disposed on the first gate insulating layer 111 to at least partially overlap the semiconductor layers A1 and A2. The gate electrodes G1 and G2 include molybdenum (Mo), aluminum (Al), copper (Cu), titanium (Ti), and the like, and may include a single layer or multiple layers. For example, the gate electrodes G1 and G2 may include a single layer of Mo.

While the gate electrodes G1 and G2 are disposed on the first gate insulating layer 111 in the drawings, in an embodiment, the gate electrodes G1 and G2 may be disposed on an upper surface of the second gate insulating layer 113. Also, the gate electrodes G1 and G2 of thin-film transistors TFT1 and TFT2 may be disposed on a same layer or may be disposed on different layers.

The lower electrode CE1 of the storage capacitor Cst may include a same material or a similar material as that of the gate electrodes G1 and G2 and disposed on the first gate insulating layer 111. The upper electrode CE2 of the storage capacitor Cst overlaps the lower electrode CE1 with the second gate insulating layer 113 therebetween, and forms capacitance. The second gate insulating layer 113 may function as a dielectric layer of the storage capacitor Cst.

As illustrated in FIG. 6, the lower electrode CE1 of the storage capacitor Cst may overlap a first thin-film transistor TFT1. For example, the gate electrode G1 of the first thin-film transistor TFT1 may function as the lower electrode CE1 of the storage capacitor Cst.

In order to form the gate electrodes G1 and G2 and the lower electrode CE1 of the storage capacitor Cst, a metal layer (not shown) may be formed on the entire surface of the substrate 100 and patterned. The metal layer may be formed by a deposition method such as CVD, plasma enhanced CVD (PECVD), low pressure CVD (LPCVD), physical vapor deposition (PVD), sputtering, or atomic layer deposition (ALD) or the like, and is not limited thereto. A method of forming the upper electrode CE2 of the storage capacitor Cst may be the same as the method of forming the gate electrodes G1 and G2 and the lower electrode CE1 of the storage capacitor Cst.

The interlayer insulating layer 115 is formed on the entire surface of the substrate 100 to cover the upper electrode CE2 of the storage capacitor Cst. The interlayer insulating layer 115 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), and the like, and may be formed by a deposition method such as CVD or sputtering, but is not limited thereto.

A first contact hole is formed, which passes through the first and second gate insulating layers 111 and 113 and the interlayer insulating layer 115 and exposes the source and/or drain regions of the semiconductor layers A1 and A2.

Source electrodes S1 and S2 and drain electrodes D1 and D2 may include a conductive material including molybdenum (Mo), aluminum (Al), copper (Cu), titanium (Ti), and the like, and may include multiple layers or a single layer including the above materials. For example, the source electrodes S1 and S2 and the drain electrodes D1 and D2 may have a multi-layer structure of Ti/Al/Ti. The source electrodes S1 and S2 and the drain electrodes D1 and D2 may be connected to the source region or the drain region of the semiconductor layers A1 and A2 through the first contact hole.

The source electrodes S1 and S2 and the drain electrodes D1 and D2 may be covered with an inorganic protective layer (not shown). The inorganic protective layer may include a single layer or a multi-layer layer of silicon nitride (SiNₓ) and silicon oxide (SiOₓ). The inorganic protective layer may be introduced to cover and protect some or a number of wires disposed on the interlayer insulating layer 115.

The planarization layer 117 may be disposed on the interlayer insulating layer 115 to cover the source electrodes S1 and S2 and the drain electrodes D1 and D2. The planarization layer 117 may be formed as a single layer or multiple layers including an organic material or an inorganic material. The planarization layer 117 may include a general-purpose polymer such as benzocyclobutene (BCB), polyimide, hexamethyldisiloxane (HMDSO), polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and a blend thereof. On the other hand, the planarization layer 117 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), and the like within the spirit and the scope of the disclosure. After forming the planarization layer 117, chemical mechanical polishing may be performed to provide a flat top surface. A second contact hole passing through the planarization layer 117 and exposing the drain electrodes D1 and D2 may be formed through a mask process.

The pixel electrode 210 is formed on the planarization layer 117 in operation S20.

The pixel electrode 210 may be formed by depositing a conductive layer on the entire upper surface of the planarization layer 117 and performing a mask process and an etching process.

The pixel electrode 210 may include a (semi)-light transmissive electrode or a reflective electrode. In an embodiment, the pixel electrode 210 may include a reflective layer including Ag, Mg, Al, Pt, Pd, Au, Ni, Nd, Ir, Cr, and a compound thereof, and a transparent or translucent electrode layer formed on the reflective layer. The transparent or translucent electrode layer may include at least one selected from among indium tin oxide (ITO), indium zinc oxide (IZO), zinc oxide (ZnO), indium oxide (In₂O₃), indium gallium oxide (IGO), and aluminum zinc oxide (AZO). In an embodiment, the pixel electrode 210 may include ITO/Ag/ITO.

As the second contact hole exposing the drain electrodes D1 and D2 is formed in the planarization layer 117, the pixel electrode 210 may be connected to the drain electrodes D1 and D2 through the second contact hole.

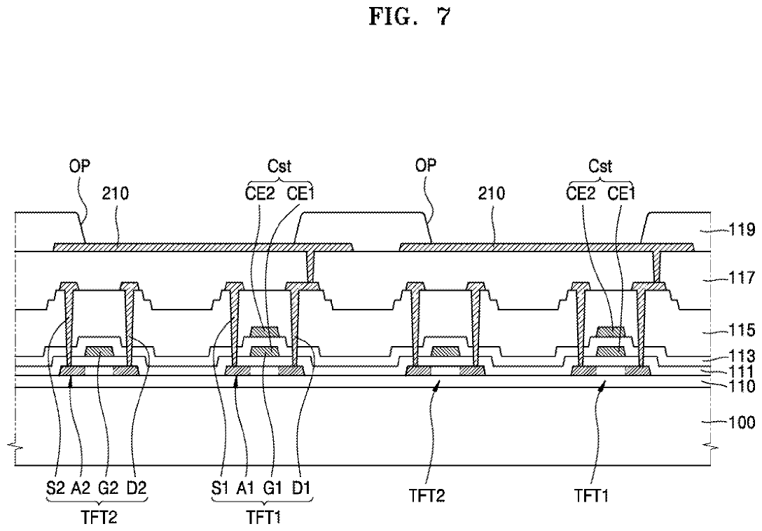

As illustrated in FIG. 7, the pixel-defining layer 119 having an opening OP that covers edges of the pixel electrode 210 and exposes a central portion thereof is formed on the entire upper surface of the planarization layer 117 in operation S30. The pixel-defining layer 119 may include at least one organic insulating materials selected from polyimide, polyamide, an acrylic resin, BCB, and a phenol resin, and may be formed by spin coating or the like within the spirit and the scope of the disclosure. The pixel-defining layer 119 may include photosensitive polyimide (PSPI).

The pixel-defining layer 119 may increase a distance between the edges of the pixel electrode 210 and the opposite electrode 230 (see FIG. 11) on the pixel electrode 210, thereby preventing an arc or the like from occurring at the edges of the pixel electrode 210.

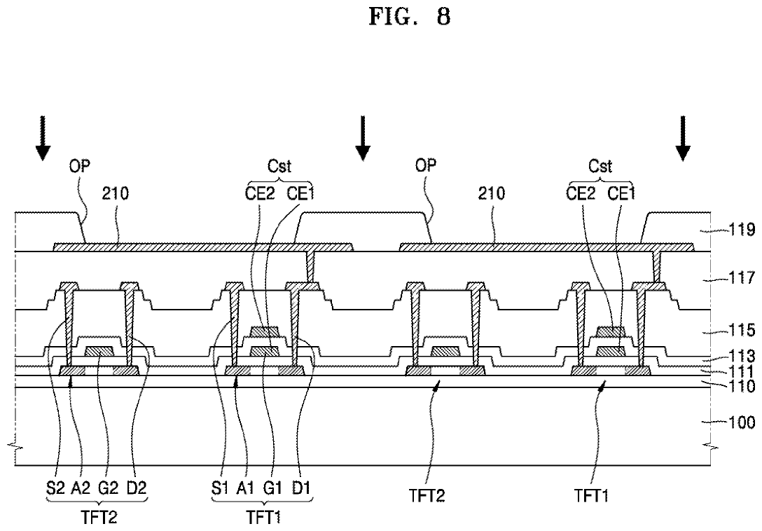

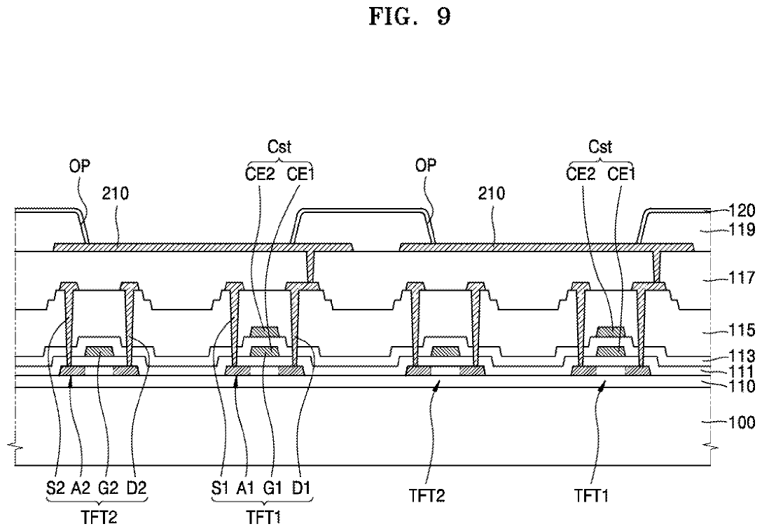

Referring to FIGS. 8 and 9, the cured layer 120 is formed on the pixel-defining layer 119 by plasma treatment in operation S40.

A method of manufacturing a display apparatus according to an embodiment may include preparing the substrate 100; forming the pixel electrode 210 on the substrate 100; forming the pixel-defining layer 119 disposed on the pixel electrode 210 and having the opening OP exposing at least a portion of the pixel electrode 210; and forming the cured layer 120 on the pixel-defining layer 119 by plasma treatment, wherein the cured layer 120 is formed through cross-linking of materials included in the pixel-defining layer 119, and the cured layer 120 may have weaker moisture adsorption capacity than the pixel-defining layer 119. The fact that the cured layer 120 has a weaker moisture adsorption capacity than pixel-defining layer 119 may mean that cured layer 120 is more hydrophobic than pixel-defining layer 119.

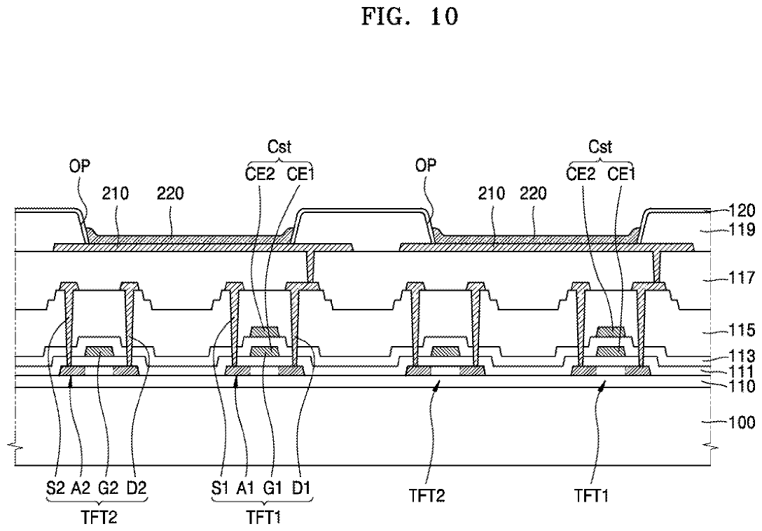

In case that moisture is adsorbed to the pixel-defining layer 119 during the process after the forming of the pixel-defining layer 119, a light-emitting region of an emission layer included in the intermediate layer 220 (see FIG. 10) may be contracted, thereby reducing the light emission performance. According to the disclosure, absorption of moisture may be prevented by forming the cured layer 120 on the pixel-defining layer 119 by plasma treatment.

In an embodiment, the pixel-defining layer 119 may include PSPI. The forming of a cured layer on the pixel-defining layer 119 by plasma-treatment (S40) may include an operation S401 in which chain scission occurs, in which carbon-nitrogen bonds of a PSPI monomer included in the pixel-defining layer 119 are broken. Operation S40 may include, after operation S401, an operation S402, in which the PSPI monomer, which has undergone chain scission, forms a crosslinked structure through carbon-carbon bonds.

Since the carbon-nitrogen bonding energy of the PSPI monomer is about 3.2 eV, the bond may be broken using light of a short wavelength band. In an embodiment, the forming of the cured layer 120 on the pixel-defining layer 119 by plasma treatment may be performed using light of a wavelength in a range of about 300 nm to about 500 nm.

In an embodiment, the forming of the cured layer 120 on the pixel-defining layer 119 by plasma treatment may be performed using a gas containing helium (He). This is because, in case that helium (He) gas is used, intensity of light of a short wavelength band exhibits a peak. A flow rate of the gas containing helium (He) may be performed in a range of about 1000 sccm to about 2000 sccm.

In an embodiment, pressure may be applied during plasma treatment, and source power for generating plasma may be applied. For example, helium (He) gas may be turned into an ionized gas through the source power. In an embodiment, more bias power may be applied. In case that applying the bias power, the gas ionized due to the source power is drawn to a voltage of an opposite polarity by the bias power, thus increasing kinetic energy.

In an embodiment, the plasma treatment may be performed at a process pressure of in a range of about 8 mT to about 50 mT, and with process power, for example, a source power in a range of about 2500 W to about 3500 W and a bias power in a range of about 500 W to about 1500 W. The plasma treatment may be performed in a range for about 30 seconds to about 50 seconds.

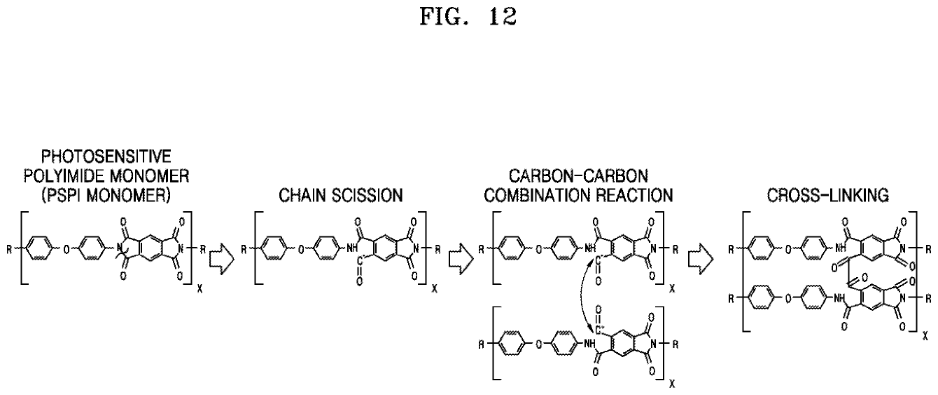

The cured layer 120 formed on the pixel-defining layer 119 by plasma treatment may include a crosslinked structure formed by PSPI monomers, which have undergone chain scission, through carbon-carbon bonds with each other, and may thus have a stable bonding structure (see FIG. 12). Accordingly, the cured layer 120 may include a material having a different chemical structure from that of a material included in the pixel-defining layer 119. The cured layer 120 may have weaker moisture absorption power than the pixel-defining layer 119. The cured layer 120 may be hydrophobic.

For example, by forming the cured layer 120 on the pixel-defining layer 119, contraction of the light-emitting region due to adsorption of moisture in a subsequent process may be prevented.

Referring to FIG. 10, the intermediate layer 220 may be formed on the pixel electrode 210 in operation S50.

The intermediate layer 220 is formed in the opening OP of the pixel-defining layer 119. The intermediate layer 220 may include a low-molecular weight material or a polymer material. The intermediate layer 220 may be formed by a vacuum deposition method, a screen printing method or an inkjet printing method, a laser induced thermal imaging (LITI) method, or the like within the spirit and the scope of the disclosure.

The intermediate layer 220 of the organic light-emitting diode (OLED) may include an organic emission layer. The organic emission layer may include an organic material including a fluorescent or phosphorescent material emitting red, green, blue, or white light. The organic emission layer may include a low-molecular weight organic material or a polymer organic material, and below and above the organic emission layer, a functional layer such as a hole transport layer (HTL), a hole injection layer (HIL), an electron transport layer (ETL), and an electron injection layer (EIL) may be optionally further disposed. The intermediate layer 220 may be disposed to correspond to each of pixel electrodes 210. However, the disclosure is not limited thereto. Other various modifications may be made; for example, the intermediate layer 220 may include an integral layer over the pixel electrodes 210.

Referring to FIG. 11, the opposite electrode 230 may be formed to correspond to organic light-emitting diodes (OLEDs) in operation S60.

The opposite electrode 230 may cover the display area DA of the substrate 100 (see FIG. 1) through an open mask. The opposite electrode 203 may be formed by a deposition method such as CVD, PECVD, LPCVD, PVD, sputtering, or ALD or the like within the spirit and the scope of the disclosure.

The opposite electrode 230 may include a light-transmissive electrode or a reflective electrode. In an embodiment, the opposite electrode 230 may include a transparent or translucent electrode, and include a metal thin film having a small work function including Li, Ca, LiF/Ca, LiF/Al, Al, Ag, Mg, and compounds thereof. A transparent conductive oxide (TCO) layer such as ITO, IZO, ZnO, or In₂O₃ may be further disposed on the metal thin film.

Referring to FIG. 11, the display apparatus according to an embodiment may include: the substrate 100; the pixel electrode 210 disposed on the substrate 100; the pixel-defining layer 119 disposed on the pixel electrode 210 and having the opening OP exposing at least a portion of the pixel electrode 210; the cured layer 120 disposed on the pixel-defining layer 119; and the opposite electrode 230 disposed on the cured layer 120, wherein the cured layer 120 may include a material in which a crosslinked structure is formed through carbon-carbon bonds.

In an embodiment, the pixel-defining layer 119 may include PSPI. The cured layer 120 may include a material having a different chemical structure from that of a material included in the pixel-defining layer 119. The material forming the crosslinked structure in the cured layer 120 may include a PSPI monomer.

The cured layer 120 may have a stable bonding structure in which the PSPI monomer forms carbon-carbon bonds (see FIG. 12). The cured layer 120 may be hydrophobic. For example, by including the cured layer 120 on the pixel-defining layer 119, contraction of the light-emitting region due to adsorption of moisture in the process may be prevented.

In an embodiment, a thickness of the cured layer 120 may be in a range of about 100 Å to about 500 Å.

In an embodiment, the intermediate layer 220 may be further included on the pixel electrode 210. The opposite electrode 230 may cover the intermediate layer 220 and the cured layer 120.

FIG. 12 is a schematic diagram illustrating chemical formulae of materials that may be included in an embodiment.

Referring to FIG. 12, the forming of a cured layer on the pixel-defining layer 119 by plasma treatment (S40, see FIG. 4) may include operation S401 in which chain scission occurs, in which carbon-nitrogen bonds of a PSPI monomer included in the pixel-defining layer 119 are broken. Operation S40 may include operation S402 in which the PSPI monomer, which has under gone chain scission, forms a crosslinked structure through carbon-carbon bonds.

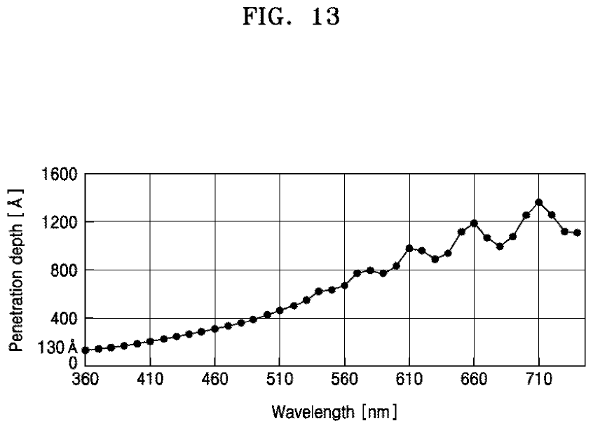

FIG. 13 shows a graph showing a thickness whereby light penetrates through the pixel-defining layer 119 according to wavelengths during plasma treatment.

A method of manufacturing a display apparatus, according to an embodiment, may include preparing the substrate 100; forming the pixel electrode 210 on the substrate 100; forming the pixel-defining layer 119 disposed on the pixel electrode 210 and having the opening OP exposing at least a portion of the pixel electrode 210; and forming the cured layer 120 on the pixel-defining layer 119 by plasma treatment, wherein the cured layer 120 is formed through cross-linking of materials included in the pixel-defining layer 119, and the cured layer 120 may have weaker moisture adsorption capacity than the pixel-defining layer 119.

In an embodiment, the forming of the cured layer 120 on the pixel-defining layer 119 by plasma treatment may be performed using light of a wavelength in a range of about 300 nm to about 500 nm.

Referring to FIG. 13, in case that using light of a wavelength in a range of about 300 nm to about 50 nm, a thickness whereby the pixel-defining layer 119 is penetrated is in a range of about 100 Å to about 500 Å. Accordingly, in an embodiment, a thickness of the cured layer 120 may be in a range of about 100 Å to about 500 Å.

According to an embodiment as described above, a display apparatus including a light-emitting element having improved light emission performance and a method of manufacturing the display apparatus may be implemented. However, the scope of the disclosure is not limited by the above-described effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope and as defined by the following claims.

What is claimed is:

1. A display apparatus comprising:
a pixel electrode disposed on a substrate;
a pixel-defining layer disposed on the pixel electrode and having an opening exposing at least a portion of the pixel electrode;
a cured layer disposed on the pixel-defining layer; and
an opposite electrode disposed on the cured layer,
wherein the cured layer includes a material forming a crosslinked structure through carbon-carbon bonds.

2. The display apparatus of claim 1, wherein a thickness of the cured layer is in a range of about 100 Å to about 500 Å.

3. The display apparatus of claim 1, wherein the cured layer is hydrophobic.

4. The display apparatus of claim 1, wherein the cured layer has a different chemical structure from a chemical structure of a material included in the pixel-defining layer.

5. The display apparatus of claim 4, wherein the pixel-defining layer comprises photosensitive polyimide (PSPI).

6. The display apparatus of claim 5, wherein the material forming the crosslinked structure in the cured layer comprises a PSPI monomer.

7. The display apparatus of claim 1, further comprising:
an intermediate layer disposed on the pixel electrode.

8. The display apparatus of claim 7, wherein the opposite electrode covers the intermediate layer and the cured layer.

9. A method of manufacturing a display apparatus, the method comprising:
forming a pixel electrode on a substrate;
forming a pixel-defining layer disposed on the pixel electrode and having an opening exposing at least a portion of the pixel electrode; and
forming a cured layer on the pixel-defining layer by plasma treatment, wherein
the cured layer is formed by cross-linking of a material included in the pixel-defining layer, and
the cured layer has weaker moisture adsorption capacity than the pixel-defining layer.

10. The method of claim 9, wherein a thickness of the cured layer is in a range of about 100 Å to about 500 Å.

11. The method of claim 9, wherein the pixel-defining layer comprises photosensitive polyimide (PSPI).

12. The method of claim 9, wherein the forming of the cured layer on the pixel-defining layer by plasma treatment comprises chain scission in which carbon-nitrogen bonds are broken in the pixel-defining layer.

13. The method of claim 12, further comprising:
forming a crosslinked structure through carbon-carbon bonds in the pixel-defining layer after the chain scission.

14. The method of claim 9, wherein the forming of the cured layer on the pixel-defining layer by plasma treatment is performed using light of a wavelength in a range of about 300 nm to about 500 nm.

15. The method of claim 9, wherein the forming of the cured layer on the pixel-defining layer by plasma treatment is performed by using a gas containing helium (He).

16. The method of claim 15, wherein the forming of the cured layer on the pixel-defining layer by plasma treatment is performed in a range of about 30 seconds to about 50 seconds.

17. The method of claim 15, wherein a flow rate of the gas containing helium (He) is in a range of about 1000 sccm to about 2000 sccm.

18. The method of claim 15, wherein the forming of the cured layer on the pixel-defining layer by plasma treatment is performed with a process power comprising a source power in a range of about 2500 W to about 3500 W and a bias power in a range of about 500 W to about 1500 W, at a process pressure in a range of about 8 mT to about 50 mT.

19. The method of claim 9, further comprising:
forming an intermediate layer disposed on the pixel electrode after the forming of the cured layer.

20. The method of claim 19, further comprising:
forming an opposite electrode covering the intermediate layer and the cured layer after the forming of the intermediate layer.
